(19) United States
(12) Patent Application Publication
(10) Pub. No.: US 2024/0284656 A1
(43) Pub. Date: Aug. 22, 2024

(54) SEMICONDUCTOR DEVICE

(71) Applicant: Kioxia Corporation, Tokyo (JP)

(72) Inventors: Kaito ODA, Yokkaichi Mie (JP); Daichi SUGAWARA, Yokkaichi Mie (JP)

(73) Assignee: Kioxia Corporation, Tokyo (JP)

(21) Appl. No.: 18/421,704

(22) Filed: Jan. 24, 2024

(30) Foreign Application Priority Data
Jan. 27, 2023 (JP) 2023-010585

(51) Int. Cl. H10B 12/00

(52) U.S. Cl. CPC H10B 12/315; H10B 12/05

(57) ABSTRACT

A semiconductor device according to an embodiment includes: a first electrode: a first insulating layer provided on the first electrode; a gate electrode provided on the first insulating layer; a second insulating layer provided on the gate electrode; a second electrode provided on the second insulating layer; and a channel layer penetrating the second insulating layer, the gate electrode, and the first insulating layer and connected to the first and second electrodes, in which the channel layer includes: a first semiconductor layer based on a composite oxide semiconductor containing a plurality of metals; a second semiconductor layer provided between the first semiconductor layer and the first electrode; and a third semiconductor layer provided between the first semiconductor layer and the second electrode, and the second and third semiconductor layers are based on another composite oxide semiconductor containing metals of same types as the metals of the first semiconductor layer, the another composite oxide semiconductor having a metal among the plurality of metals having a higher carrier concentration than other metals, the metal having a higher content rate in the second and third semiconductor layers than in the first semiconductor layer.

### CROSS-REFERENCE TO RELATED APPLICATIONS

This application is based upon and claims the benefit of priority from Japanese Patent Application No. 2023-010585, filed on Jan. 27, 2023; the entire contents of which are incorporated herein by reference.

### FIELD

Embodiments of the present invention relate generally to a semiconductor device.

### BACKGROUND

There are known semiconductor devices configured as a vertical transistor using a composite oxide semiconductor as a channel layer. A gate electrode is connected to a side surface of the channel layer, and an insulating layer such as an interlayer insulating layer is provided therearound.

With miniaturization of the semiconductor devices, the cross-sectional area of the channel layer in a connection direction of the gate electrode and the layer thickness of the insulating layer serving as the interlayer insulating layer are also reduced. Therefore, it is desired to further reduce the resistance of vertical transistors.

### BRIEF DESCRIPTION OF THE DRAWINGS

FIGS. 1A to 1C are schematic diagrams illustrating an example of a structure of a semiconductor device according to a first embodiment;

FIGS. 2Aa to 2Eb are cross-sectional views sequentially illustrating an exemplary part of a procedure of a manufacturing method of the semiconductor device according to the first embodiment;

FIGS. 3Aa to 3Eb are cross-sectional views sequentially illustrating an exemplary part of the procedure of the manufacturing method of the semiconductor device according to the first embodiment;

FIGS. 4Aa to 4Eb are cross-sectional views sequentially illustrating an exemplary part of the procedure of the manufacturing method of the semiconductor device according to the first embodiment;

FIGS. 5A and 5B are schematic diagrams illustrating an example of a structure of a semiconductor device according to a modification of the first embodiment;

FIGS. 6Aa to 6Eb are cross-sectional views illustrating an exemplary part of a procedure of a manufacturing method of the semiconductor device according to the modification of the first embodiment;

FIGS. 7A to 7D are schematic diagrams illustrating an example of a structure of a semiconductor device according to a second embodiment;

FIGS. 8Aa to 8Eb are cross-sectional views illustrating an exemplary part of a procedure of a manufacturing method of the semiconductor device according to the second embodiment;

FIG. 9 is a schematic graph illustrating a relationship between the electrical characteristics and the layer thickness of an interlayer insulating layer of the semiconductor devices according to the second embodiment and a comparative example;

FIGS. 10A to 10D are schematic diagrams illustrating an example of a structure of a semiconductor device according to a modification of the second embodiment;

FIGS. 11Aa to 11E are cross-sectional views sequentially illustrating an exemplary part of a procedure of a manufacturing method of the semiconductor device according to the modification of the second embodiment;

FIGS. 12Aa to 12C are cross-sectional views sequentially illustrating an exemplary part of the procedure of the manufacturing method of the semiconductor device according to the modification of the second embodiment;

FIGS. 13Aa to 13Bb are cross-sectional views sequentially illustrating an exemplary part of the procedure of the manufacturing method of the semiconductor device according to the modification of the second embodiment; and

FIGS. 14A to 14C are schematic diagrams illustrating exemplary structures of semiconductor devices according to other modifications.

### DETAILED DESCRIPTION

A semiconductor device according to an embodiment includes: a first electrode; a first insulating layer provided on the first electrode; a gate electrode provided on the first insulating layer; a second insulating layer provided on the gate electrode; a second electrode provided on the second insulating layer; a channel layer having one end connected to the first electrode and another end connected to the second electrode; and a gate insulating layer provided between the channel layer and the gate electrode, between the channel layer and the first insulating layer, and between the channel layer and the second insulating layer, in which the channel layer includes: a first semiconductor layer based on a composite oxide semiconductor containing a plurality of metals; a second semiconductor layer provided between the first semiconductor layer and the first electrode; and a third semiconductor layer provided between the first semiconductor layer and the second electrode, and the second and third semiconductor layers are based on another composite oxide semiconductor containing metals of same types as the metals of the first semiconductor layer, the another composite oxide semiconductor having a metal among the plurality of metals having a higher carrier concentration than other metals, the metal having a higher content rate in the second and third semiconductor layers than in the first semiconductor layer.

Hereinafter, embodiments of the present invention will be described in detail with reference to the drawings. Note that the present invention is not limited by the embodiments. In addition, components in the following embodiments include those that can be easily conceived by those skilled in the art or those that are substantially the same.

### First Embodiment

Hereinafter, a first embodiment will be described in detail with reference to the drawings.

### (Configuration Example of Semiconductor Device)

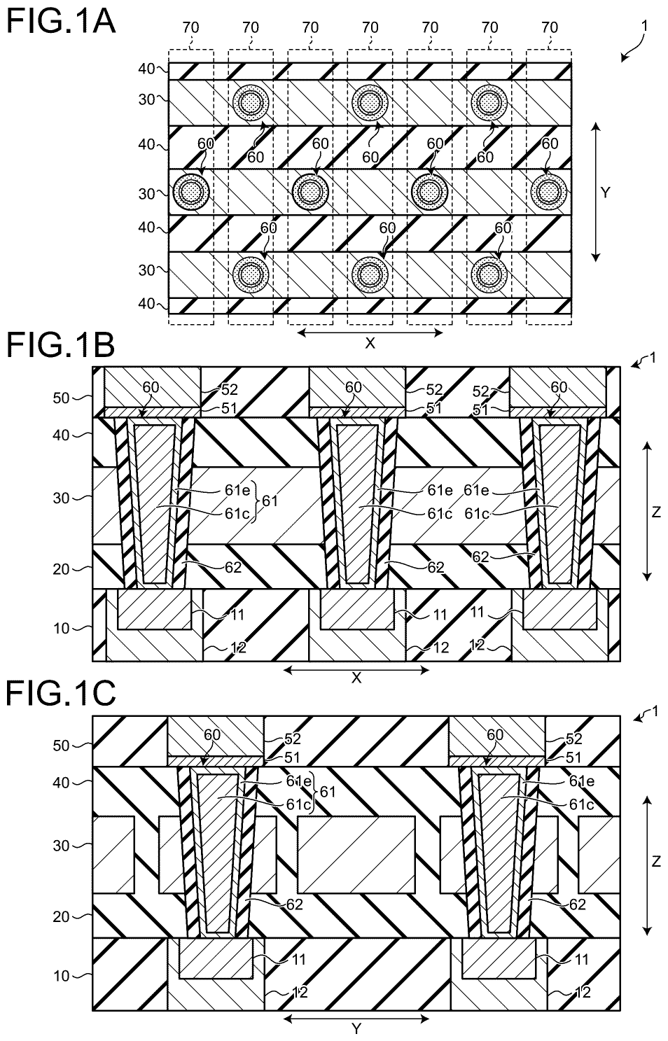

FIGS. 1A to 1C are schematic diagrams illustrating an example of a structure of a semiconductor device 1 according to a first embodiment. FIG. 1A is an XY cross-sectional view of the semiconductor device 1 at a position at the height of gate electrodes 30 described later. FIG. 1B is a cross-sectional view of the semiconductor device 1 taken in an X direction. FIG. 1C is a cross-sectional view of the semiconductor device 1 taken in a Y direction.

Incidentally, in the present specification, both the X direction and the Y direction extend along surfaces of the gate electrodes 30 described later, and the X direction and the Y direction are orthogonal to each other. A Z direction is a stacking direction of layers included in the semiconductor device 1 and is orthogonal to the X direction and the Y direction.

Moreover, the extending direction of the gate electrodes 30 may be referred to as a first direction, and the first direction is a direction along the X direction. Furthermore, a direction which is an extending direction of bit lines 70 described later and intersects with the first direction may be referred to as a second direction, and the second direction is a direction along the Y direction. However, since the semiconductor device 1 may include manufacturing errors, the first direction and the second direction are not necessarily orthogonal to each other.

As illustrated in FIGS. 1A to 1C, the semiconductor device 1 includes lower electrodes 11 as first electrodes, the gate electrodes 30, upper electrodes 51 as second electrodes, and pillars 60.

The lower electrodes 11, the gate electrodes 30, the upper electrodes 51, and the pillars 60 are provided above a substrate (not illustrated) such as a silicon substrate. More specifically, insulating layers 10 and 20, the gate electrodes 30, and the insulating layers 40 and 50 are provided on the substrate in the order mentioned. The layer thickness of each of the gate electrodes 30 and the insulating layers 20 and 40 is, for example, about several tens nanometers.

The insulating layer 10 is, for example, a silicon nitride layer or the like. In the insulating layer 10, contacts 12 penetrating the insulating layer 10 are included at predetermined intervals in the X direction and the Y direction. A contact 12 is, for example, an amorphous silicon layer or the like, and is connected to the substrate via a source line (not illustrated) or directly.

In a contact 12, a lower electrode 11 such as an indium tin oxide (ITO) layer is buried. As a result, the lower electrodes 11 fall to a substrate potential. Note that the upper surfaces of the insulating layer 10, the contacts 12, and the lower electrodes 11 are positioned on substantially the same plane, and the upper surfaces of the lower electrodes 11 are not covered with the contacts 12 nor the insulating layer 10.

On the insulating layer 10, the insulating layer 20 that covers the upper surfaces of the insulating layer 10, the contacts 12, and the lower electrodes 11 is provided. The insulating layer 20 as the first insulating layer is, for example, a SiO layer or the like. The insulating layer 20 may be a low-k layer such as a SiOC layer or an air gap layer.

The plurality of gate electrodes 30 extending along the X direction and arranged at predetermined intervals in the Y direction are provided on the insulating layer 20. The plurality of gate electrodes 30 are tungsten layers or the like and are provided at positions overlapping the lower electrodes 11 in the Z direction, the lower electrodes 11 arranged in a grid pattern in the X direction and the Y direction. The above-described insulating layer 20 is also provided between the gate electrodes 30 adjacent to each other in the Y direction. However, the insulating layer 40 that is an upper layer on the gate electrodes 30 may be filled between the gate electrodes 30 adjacent to each other in the Y direction.

The insulating layer 40 covering these gate electrodes 30 is provided on the plurality of gate electrodes 30. The insulating layer 40 as the second insulating layer may be made of the same type of material as that of the insulating layer 20 and is, for example, a SiO layer or the like, or a low-k layer such as a SiOC layer or an air gap layer.

The insulating layer 50 such as a SiO layer is provided on the insulating layer 40. On the lower surface side of the insulating layer 50, the plurality of upper electrodes 51 are provided at positions overlapping the plurality of lower electrodes 11 in the Z direction. Similarly to the lower electrodes 11, the upper electrodes 51 are, for example, an ITO layer or the like and is connected to the bit lines 70 further above the insulating layer 50 via plugs 52 penetrating the insulating layer 50. The plurality of bit lines 70 each extends along the Y direction and is arranged at predetermined intervals in the X direction.

At positions interposed between the lower electrodes 11 and the upper electrodes 51, the respective pillars 60 penetrating the insulating layer 40, the gate electrodes 30 corresponding to the positions, and the insulating layer 20 are included. Each of the plurality of pillars 60 includes a channel layer 61 and a gate insulating layer 62.

The channel layer 61 includes semiconductor layers 61c and 61e and is connected to a lower electrode 11 and an upper electrode 51 through the insulating layer 40, a gate electrode 30, and the insulating layer 20.

The semiconductor layer 61c as a first semiconductor layer is a composite oxide semiconductor layer such as an IGZO layer which is an oxide layer of indium (In), gallium (Ga), and zinc (Zn) and is included in the central portion to be a core of the pillar 60.

The semiconductor layer 61e covers the upper end, the lower end, and the sidewall of the semiconductor layer 61c. The layer thickness of the semiconductor layer 61e is, for example, less than or equal to 5 nm. The semiconductor layer 61e is a composite oxide semiconductor layer such as an IGZO layer containing the same type of metal as that of the semiconductor layer 61c. However, in the semiconductor layer 61e, the content rate of a metal, having a higher carrier concentration among the metals contained in the semiconductor layer 61e, is higher than that of the semiconductor layer 61c.

For example, among the metals contained in the IGZO layer, the carrier concentration of In is higher than that of other metals such as Ga and Zn. Therefore, in a case where the semiconductor layers 61c and 61e are, for example, IGZO layers, the content rate of In in the semiconductor layer 61e is higher than the content rate of In in the semiconductor layer 61c.

The gate insulating layer 62 is, for example, a SiO layer or the like and covers the sidewall of the channel layer 61.

As described above, the semiconductor device 1 is configured as, for example, vertical transistors. That is, with a predetermined voltage applied from a gate electrode 30 to a channel layer 61 of a pillar 60 penetrating the gate electrode 30, a vertical transistor can be turned on. Therefore, each pillar 60 and a lower electrode 11, a gate electrode 30, and an upper electrode 51 connected to each pillar 60 may be regarded as one vertical transistor, and the semiconductor device 1 may be regarded as including a plurality of vertical transistors. Furthermore, in a vertical transistor, the gate electrode 30 that applies a voltage to the channel layer 61 functions as a word line.

By interposing the semiconductor layer 61e having a high carrier concentration at the connection portion between the lower electrode 11 and the channel layer 61 and between the upper electrode 51 and the channel layer, a Schottky resistance between the lower electrode 11 and the channel layer 61 and between the upper electrode 51 and the channel layer decreases. In addition, with the channel layer 61 including the semiconductor layer 61e having a high carrier concentration, the resistance of the channel layer 61 itself decreases as a whole.

Meanwhile, since the layer thickness of the semiconductor layer 61e is less than or equal to 5 nm, the threshold voltage of the vertical transistor, for example, is maintained at an appropriate value, and malfunction such as that the vertical transistor is not turned off is suppressed.

Incidentally, the semiconductor layer 61e interposed between the lower end of the semiconductor layer 61c and the lower electrode 11 is an example of a second semiconductor layer. The semiconductor layer 61e interposed between the upper end of the semiconductor layer 61c and the upper electrode 51 is an example of a third semiconductor layer.

In addition, the semiconductor layer 61e interposed between the sidewall of the semiconductor layer 61c and the gate electrode 30 is an example of a fourth semiconductor layer. Note that, as described above, the gate insulating layer 62 is further interposed between the outermost circumference of the channel layer 61, namely, the semiconductor layer 61e at a sidewall portion of the semiconductor layer 61c and the gate electrode 30.

### (Manufacturing Method of Semiconductor Device)

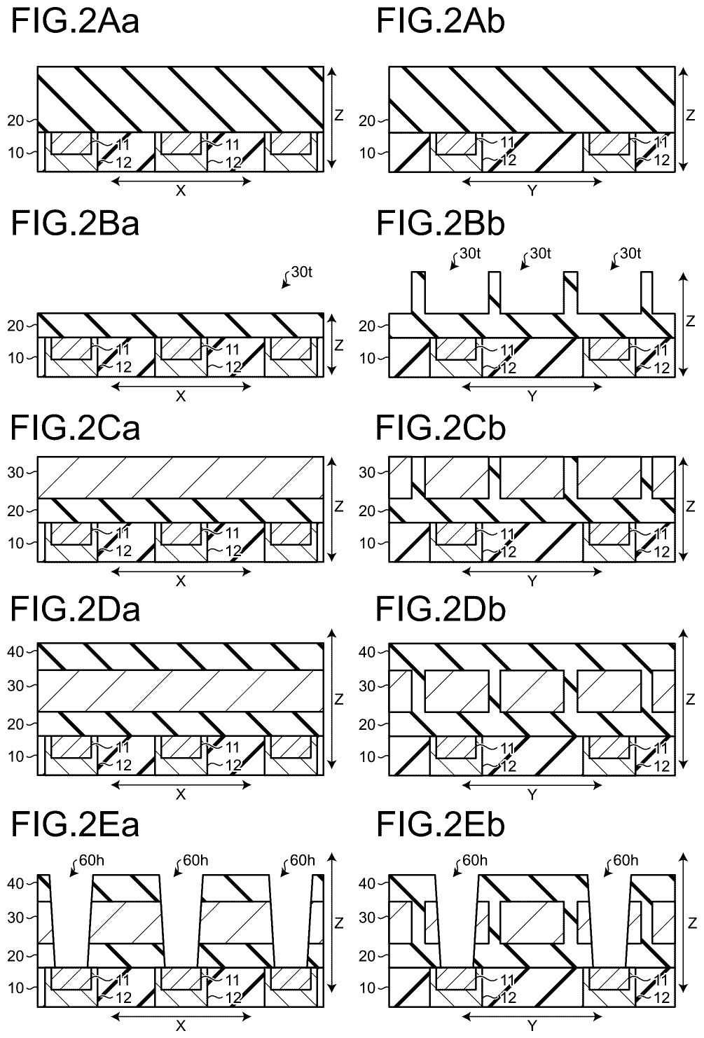

Next, an example of a manufacturing method of the semiconductor device 1 according to the first embodiment will be described with reference to FIGS. 2Aa to 4Eb. FIGS. 2Aa to 4Eb are cross-sectional views sequentially illustrating an exemplary part of a procedure of the manufacturing method of the semiconductor device 1 according to the first embodiment. More specifically, Aa to Ea among FIGS. 2Aa to 4Eb are cross-sectional views of the semiconductor device 1 in the middle of manufacturing taken in the X direction, and Ab to Eb among FIGS. 2Aa to 4Eb are cross-sectional views of the semiconductor device 1 in the middle of manufacturing taken in the Y direction.

As illustrated in FIGS. 2Aa and 2Ab, the insulating layer 10 such as a silicon nitride layer or a low-k layer is formed on the substrate. In addition, the plurality of contacts 12 penetrating the insulating layer 10 and the plurality of lower electrodes 11 buried in these contacts 12 are formed.

Then, the insulating layer 20 such as a SiO layer is formed to cover the upper surfaces of the insulating layer 10, the contacts 12, and the lower electrodes 11. At this point, the insulating layer 20 is formed to be thicker than the layer thickness that the insulating layer 20 as a semiconductor layer 1 is to finally have, for example, by the layer thickness of the gate electrodes 30 described above.

As illustrated in FIGS. 2Ba and 2Bb, a plurality of grooves 30t extending along the X direction is formed in the insulating layer 20 at predetermined intervals in the Y direction. These grooves 30t are formed at positions overlapping the plurality of lower electrodes 11 in the Z direction.

As illustrated in FIGS. 2Ca and 2Cb, a tungsten layer or the like is filled in the plurality of grooves 30t. As a result, the plurality of gate electrodes 30 is formed for which the insulating layer 20 is provided between pieces of wiring.

As illustrated in FIGS. 2Da and 2Db, the insulating layer 40 such as a SiO layer or a low-k layer covering the upper surfaces of the insulating layer 20 and the plurality of gate electrodes 30 is formed.

A method for forming the gate electrodes 30 illustrated in FIGS. 2Ba to 2Ca and 2Bb to 2Cb is also referred to as a damascene method. Note that the plurality of gate electrodes 30 may be formed by a method other than the damascene method.

As an example, the insulating layer 20 is formed from the beginning with a layer thickness that the insulating layer 20 as the semiconductor layer 1 is to finally have, and a tungsten layer or the like covering the insulating layer 20 is formed. In addition, a resist layer or the like having a pattern of the plurality of gate electrodes 30 is formed on the tungsten layer, and the tungsten layer is etched to form the plurality of gate electrodes 30.

After the resist layer is peeled off, the insulating layer 40 covering the plurality of gate electrodes 30 is formed as in FIGS. 2Da and 2Db. In this case, the insulating layer 40 is filled between the plurality of gate electrodes 30 arranged in the Y direction.

As illustrated in FIGS. 2Ea and 2Eb, a plurality of through-holes 60h penetrating the insulating layer 40, the gate electrodes 30, and the insulating layer 20 and reaching the lower electrodes 11 is formed at positions overlapping with the plurality of lower electrodes 11 in the Z direction.

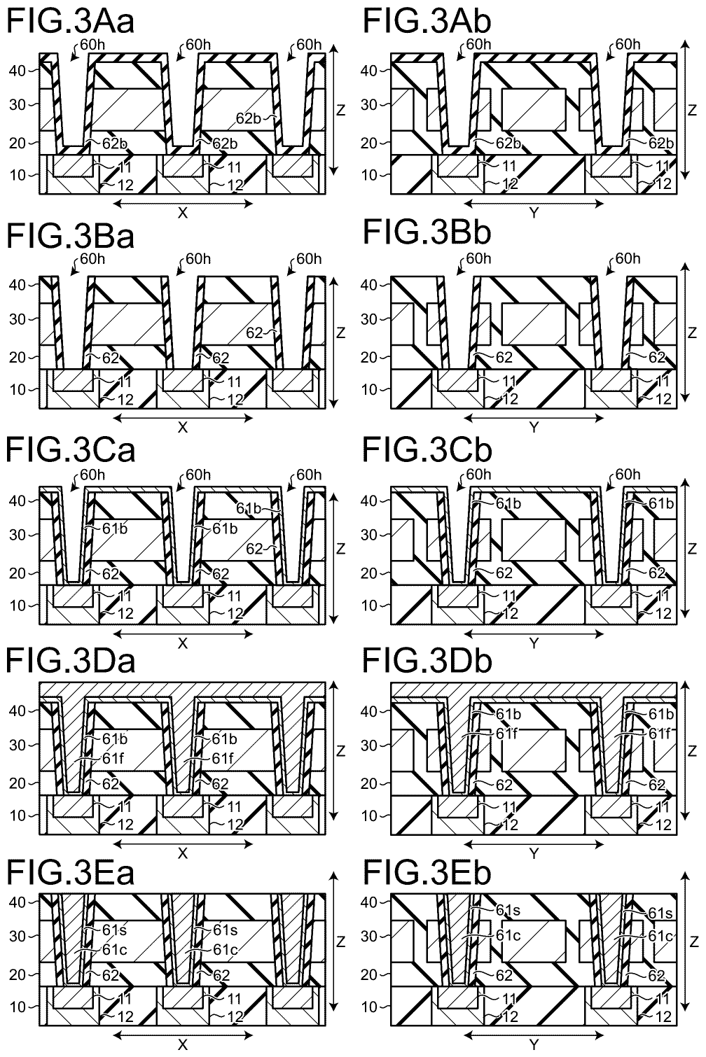

As illustrated in FIGS. 3Aa and 3Ab, a gate insulating layer 62b such as a SiO layer covering the sidewall and the bottom surface of each of the plurality of through-holes 60h is formed. At this point, the gate insulating layer 62b covers also the upper surface of the insulating layer 40.

As illustrated in FIGS. 3Ba and 3Bb, the gate insulating layer 62b is removed from the bottom surface of each of the plurality of through-holes 60h. As a result, the gate insulating layer 62b is removed also from the upper surface of the insulating layer 40, and a gate insulating layer 62 covering the sidewall of each of the plurality of through-holes 60h is formed.

As illustrated in FIGS. 3Ca and 3Cb, for example, an atomic layer deposition (ALD) method is used to form a semiconductor layer 61b such as an IGZO layer covering the sidewall and the bottom surface of each of the plurality of through-holes 60h. The semiconductor layer 61b has a high In content rate and is to be a part of the semiconductor layers 61e later. At this point, the semiconductor layer 61b also covers the upper surface of the insulating layer 40.

As illustrated in FIGS. 3Da and 3Db, a semiconductor layer 61f such as an IGZO layer is filled in the plurality of through-holes 60h by using, for example, the ALD method. The semiconductor layer 61f has an In content rate lower than that of the semiconductor layer 61b and is to be the semiconductor layers 61c at the core portions of the pillars 60 later. At this point, the semiconductor layer 61f also covers the upper surface of the insulating layer 40 via the semiconductor layer 61b.

As illustrated in FIGS. 3Ea and 3Eb, the semiconductor layers 61f and 61b on the upper surface of the insulating layer 40 are sequentially removed by chemical mechanical polishing (CMP) or the like. As a result, the semiconductor layer 61b is individually separated and becomes semiconductor layers 60s that cover the respective sidewalls and bottom surfaces of the plurality of through-holes 60h. In addition, the semiconductor layer 61f is individually separated to become the semiconductor layers 61c of the semiconductor device 1 described above. However, at this stage, the semiconductor layers 61c are filled up to the upper end of the through-holes 60h.

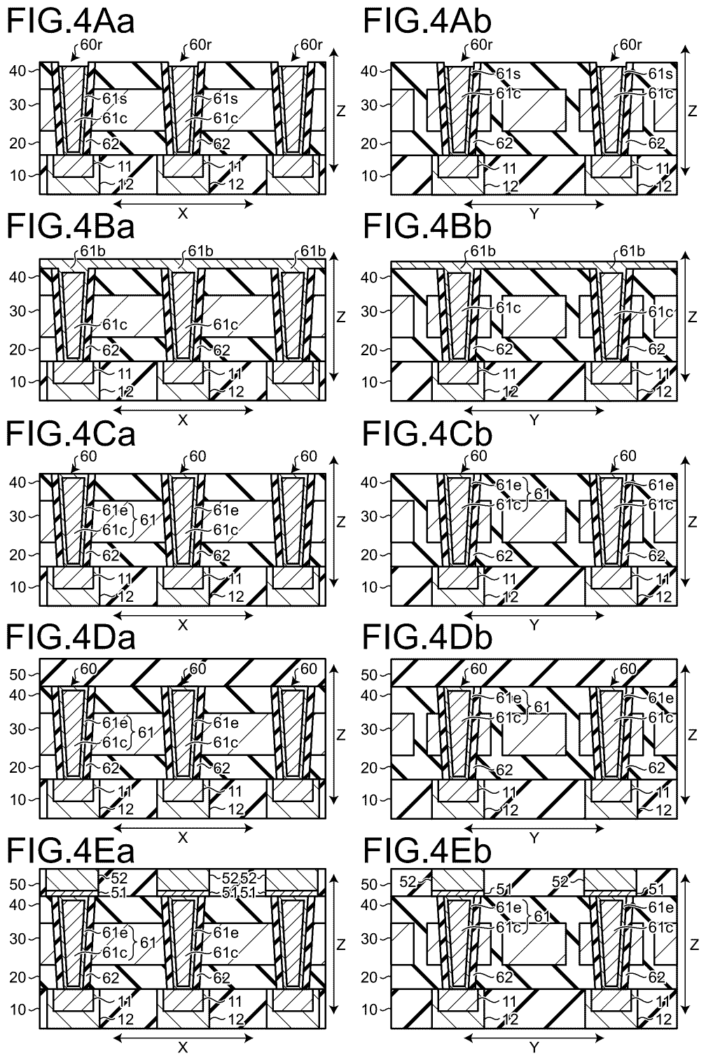

As illustrated in FIGS. 4Aa and 4Ab, the semiconductor layers 61c and 61s in the plurality of through-holes 60h are recess-etched to form recesses 60r at the respective upper ends of the plurality of through-holes 60h.

As illustrated in FIGS. 4Ba and 4Bb, a recess 60r of each of the plurality of through-holes 60h is filled with a semiconductor layer 61b such as an IGZO layer. Similarly to the semiconductor layer 61b in FIGS. 3Ca and 3Cb described above, the semiconductor layer 61b has a high In content rate and is to be a part of the semiconductor layers 61e later. At this point, the semiconductor layer 61b also covers the upper surface of the insulating layer 40.

As illustrated in FIGS. 4Ca and 4Cb, the semiconductor layer 61b on the upper surface of the insulating layer 40 is removed by CMP or the like. As a result, the semiconductor layer 61b is individually separated, and the semiconductor layers 61e each covering the upper end, the lower end, and the sidewall of a semiconductor layer 61c formed in a through-hole 60h are formed. Moreover, as a result, the plurality of pillars 60 each including a channel layer 61 including semiconductor layers 61c and 61e and a gate insulating layer 62 is formed.

As illustrated in FIGS. 4Da and 4Db, the insulating layer 50 such as a SiO layer covering the upper surfaces of the insulating layer 40 and the plurality of pillars 60 is formed.

As illustrated in FIGS. 4Ea and 4Eb, the plurality of upper electrodes 51 and the plurality of plugs 52 penetrating the insulating layer 50 and connected to the upper electrodes 51 are formed in the insulating layer 50.

In the above manner, the semiconductor device 1 according to the first embodiment is manufactured.

### Overview

The semiconductor devices configured as vertical transistors are miniaturized. In this case, in order to maintain an on-current with a reduced channel diameter, how to reduce the contact resistance is the problem to be solved.

The semiconductor device 1 according to the first embodiment includes the semiconductor layers 61e each provided between a lower electrode 11 and a semiconductor layer 61c based on a composite oxide semiconductor containing a plurality of metals and between an upper electrode 51 and the semiconductor layer 61c. The semiconductor layer 61e is based on a composite oxide semiconductor having a higher content rate of a metal, having a higher carrier concentration than other metals among a plurality of metals of the same type as those of the semiconductor layer 61c, than that of the semiconductor layer 61c.

This can reduce the Schottky resistance between the channel layer 61 and each of the lower electrode 11 and the upper electrode 51. That is, by optimizing the material of the channel layers 61, the resistance of the vertical transistors can be reduced.

According to the semiconductor device 1 of the first embodiment, the semiconductor layer 61e covers the sidewall of the semiconductor layer 61c and is also interposed between the semiconductor layer 61c and the gate insulating layer 30. As a result, the resistance of the channel layers 61 as a whole can be reduced.

According to the semiconductor device 1 of the first embodiment, the thickness of the semiconductor layer 61e on the sidewall of the semiconductor layer 61c is less than or equal to 5 nm. As a result, it is possible to suppress a decrease in the threshold voltage of the vertical transistor and to maintain good off-characteristics.

### Modification

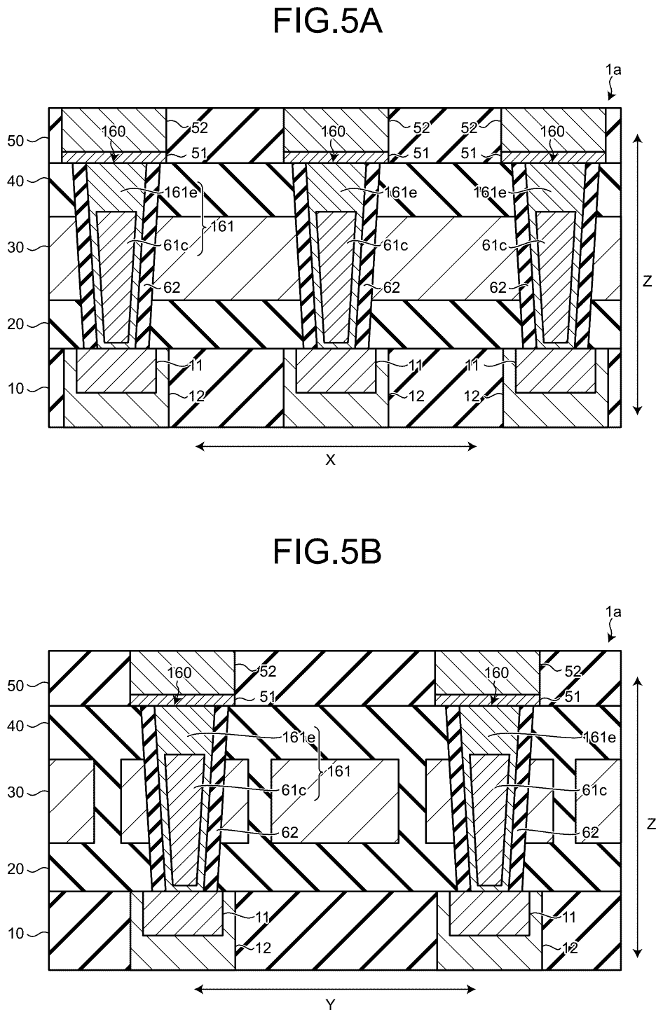

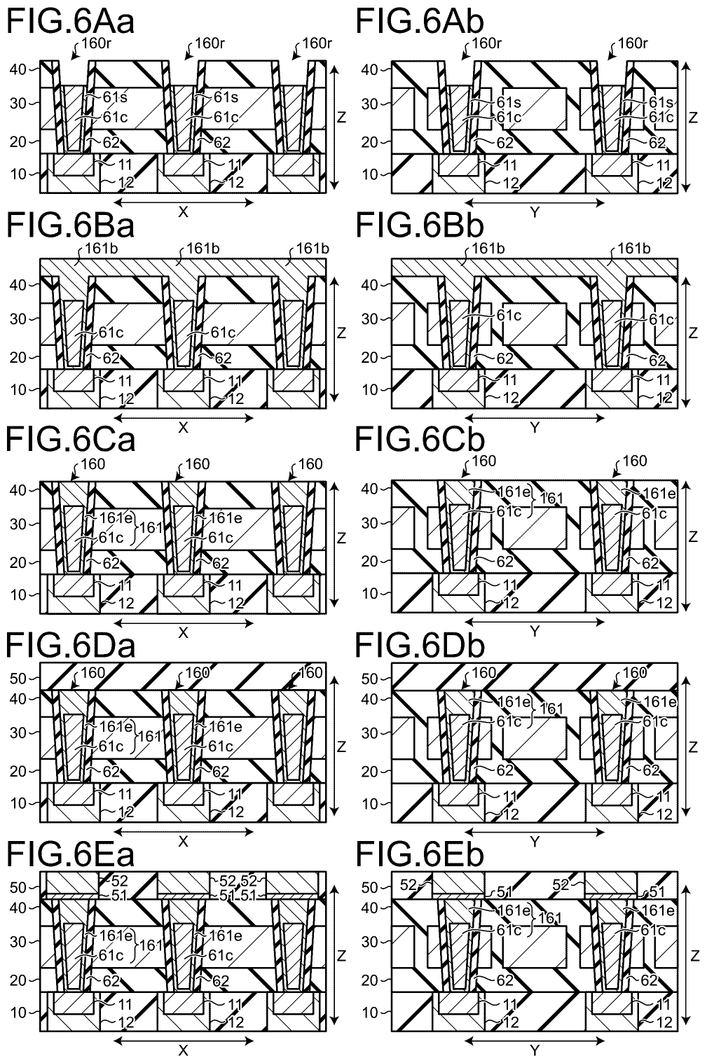

Next, a semiconductor device 1a according to a modification of the first embodiment will be described with reference to FIGS. 5A to 6Eb. The semiconductor device 1a of the modification is different from the first embodiment in that a semiconductor layer 161e having a high In content rate is formed to be thicker on the upper end side of a channel layer 161 than in other portions.

FIGS. 5A and 5B are schematic diagrams illustrating an example of a structure of the semiconductor device 1a according to the modification of the first embodiment. More specifically, FIG. 5A is a cross-sectional view of the semiconductor device 1a taken in the X direction, and FIG. 5B is a cross-sectional view of the semiconductor device 1a taken in the Y direction.

Note that, in the following drawings, similar reference numerals are given to similar components to those of the first embodiment, and description thereof may be omitted.

As illustrated in FIGS. 5A and 5B, a pillar 160 included in the semiconductor device 1a of the modification includes a semiconductor layer 161e instead of the semiconductor layer 61e of the first embodiment. The semiconductor layer 161e also covers the upper end, the lower end, and the sidewall of a semiconductor layer 61c and is a composite oxide semiconductor layer such as an IGZO layer containing the same type of metal as that of the semiconductor layer 61c. In addition, the content rate, of a metal such as In having a higher carrier concentration than other metals contained in the semiconductor layer 161e, is higher than that of the semiconductor layer 61c.

In addition, the layer thickness of the semiconductor layer 161e covering the lower end and the sidewall of the semiconductor layer 61c is, for example, less than or equal to 5 nm, similarly to the semiconductor layer 61e of the first embodiment described above. Meanwhile, the layer thickness of the semiconductor layer 161e covering the upper ends of the semiconductor layers 61c is, for example, greater than or equal to 5 nm and less than or equal to the layer thickness of an insulating layer 40. As a result, the lower surface of the semiconductor layer 161e on the upper end side of the semiconductor layer 61c is positioned above the position at the height of the upper surface of gate electrodes 30.

As described above, by setting the layer thickness of the semiconductor layer 161e between the semiconductor layer 61c and an upper electrode 51 to greater than or equal to 5 nm, the Schottky resistance between the channel layer 161 and the upper electrode 51 is further reduced. In addition, since the thick film portion of the semiconductor layer 161e does not overlap the portion sandwiched between gate electrodes 30 of the channel layer 61, that is, the portion to which a voltage is applied from a gate electrode 30, a decrease in the threshold voltage is suppressed, and the off-characteristic of the vertical transistor is maintained.

Incidentally, the semiconductor layer 161e interposed between the lower end of the semiconductor layer 61c and the lower electrode 11 is an example of the second semiconductor layer. The semiconductor layer 161e interposed between the upper end of the semiconductor layer 61c and the upper electrode 51 is an example of the third semiconductor layer. The semiconductor layer 161e interposed between the sidewall of the semiconductor layer 61c and the gate electrode 30 is an example of the fourth semiconductor layer.

FIGS. 6Aa to 6Eb are cross-sectional views illustrating an exemplary part of a procedure of a manufacturing method of the semiconductor device 1a according to the modification of the first embodiment. More specifically, FIGS. 6Aa to 6Ea are cross-sectional views of the semiconductor device 1a in the middle of manufacturing taken in the X direction, and FIGS. 6Ab to 6Eb are cross-sectional views of the semiconductor device 1a in the middle of manufacturing taken in the Y direction.

Note that, also in the manufacturing process of the semiconductor device 1a according to the modification, processing similar to that in FIGS. 2Aa to 3Eb of the above-described first embodiment is performed. Illustrated in FIGS. 6Aa to 6Eb is processing after these pieces of processing. That is, FIGS. 6Aa to 6Eb are diagrams illustrating processing after formation of the semiconductor layers 60s covering the respective sidewalls and bottom surfaces of the plurality of through-holes 60h and the semiconductor layers 60c filling the respective through-holes 60h.

As illustrated in FIGS. 6Aa and 6Ab, the semiconductor layers 61c and 61s in the plurality of through-holes 60h are recess-etched to form recesses 160r at the respective upper ends of the plurality of through-holes 60h. At this point, by lengthening the recess etching time of the upper ends of the semiconductor layers 61c and 61s, the recesses 160r are formed deeper than, for example, the recesses 60r illustrated in FIGS. 4Aa and 4Ab of the first embodiment described above. The depth of a recess 160r is, for example, greater than or equal to 5 nm and less than or equal to the layer thickness of the insulating layer 40.

As illustrated in FIGS. 6Ba and 6Bb, a recess 160r of each of the plurality of through-holes 60h is filled with a semiconductor layer 161b such as an IGZO layer. The semiconductor layer 161b has a high In content rate and is to be a part of the semiconductor layers 161e later. At this point, the semiconductor layer 161b covers also the upper surface of the insulating layer 40.

As illustrated in FIGS. 6Ca and 6Cb, the semiconductor layer 161b on the upper surface of the insulating layer 40 is removed by CMP or the like. As a result, the semiconductor layer 161b is individually separated, and the semiconductor layers 161e each covering the upper end, the lower end, and the sidewall of a semiconductor layer 61c formed in a through-hole 60h are formed. At this point, the layer thickness of the semiconductor layer 161e is thicker at the upper end of the semiconductor layer 61c than other portions.

Moreover, by the above processing, the plurality of pillars 160 each including a channel layer 161 including semiconductor layers 61c and 161e and a gate insulating layer 62 is formed.

Thereafter, also in the manufacturing method of the semiconductor device 1a according to the modification, processing similar to that in the first embodiment is performed as described below.

As illustrated in FIGS. 6Da and 6Db, an insulating layer 50 such as a SiO layer covering the upper surfaces of the insulating layer 40 and the plurality of pillars 160 is formed.

As illustrated in FIGS. 6Ea and 6Eb, the plurality of upper electrodes 51 and a plurality of plugs 52 penetrating the insulating layer 50 and connected to the upper electrodes 51 are formed in the insulating layer 50.

In the above manner, the semiconductor device 1a according to the modification of the first embodiment is manufactured.

According to semiconductor device 1a of the modification, the thickness of a semiconductor layer 161e at the upper end of a semiconductor layer 61c is greater than or equal to 5 nm and less than or equal to the thickness of the insulating layer 40. By forming the semiconductor layer 161e on an upper electrode 51 side thick in this manner, the Schottky resistance between the channel layer 61 and the upper electrode 51 can be further reduced. In addition, since the semiconductor layer 161e on the upper electrode 51 side is formed so as not to overlap with a region sandwiched by gate electrodes 30, it is possible to suppress a decrease in the threshold voltage of the vertical transistor and to maintain good off-characteristics.

According to the semiconductor device 1a of the modification, other effects similar to those of the semiconductor device 1 of the first embodiment described above are achieved.

Note that, in the above-described modification, the example of the semiconductor device 1a in which the semiconductor layers 161e are thickened at the upper ends of the semiconductor layers 61c so that the manufacturing method becomes simpler has been described. However, instead of or in addition to this, the semiconductor layers 161e may be thickened at the lower ends of the semiconductor layers 61c. By setting the thickness of the semiconductor layer 161e at at least one of the lower end or the upper end of the semiconductor layer 61c to greater than or equal to 5 nm, the Schottky resistance of the vertical transistor can be reduced.

Also in this case, it is preferable to maintain the layer thickness of the semiconductor layer 161e at the upper and lower ends of the semiconductor layer 61c at less than or equal to the layer thickness of the insulating layers 40 and 20, respectively, and to maintain the layer thickness of the semiconductor layer 161e at the sidewall of the semiconductor layer 61c at less than or equal to 5 nm, whereby it is possible to maintain good off-characteristics of the vertical transistors.

### Second Embodiment

Hereinafter, a second embodiment will be described in detail with reference to the drawings. The second embodiment is different from the first embodiment in that interlayer insulating layers provided on and under a gate electrode of a semiconductor device are partially high-k layers.

### (Configuration Example of Semiconductor Device)

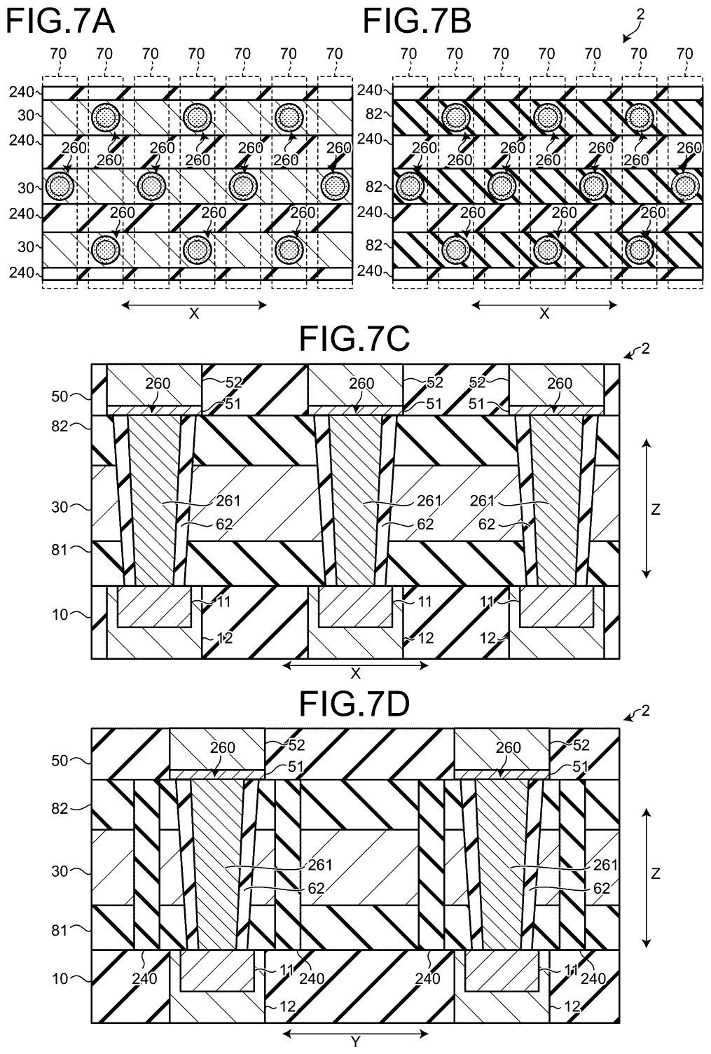

FIGS. 7A to 7D are schematic diagrams illustrating an example of a structure of a semiconductor device 2 according to the second embodiment. FIG. 7A is an XY cross-sectional view of the semiconductor device 2 at a position at the height of gate electrodes 30. FIG. 7B is an XY cross-sectional view of the semiconductor device 2 at a position at the height of an insulating layer 82 described later. FIG. 7C is a cross-sectional view of the semiconductor device 2 taken in the X direction. FIG. 7D is a cross-sectional view of the semiconductor device 2 taken in the Y direction.

Note that, in the following drawings, similar reference numerals are given to similar components to those of the first embodiment, and description thereof may be omitted.

As illustrated in FIGS. 7A to 7D, in the semiconductor device 2, insulating layers 10 and 81, gate electrodes 30, and insulating layers 82 and 50 are provided on a substrate in the order mentioned. The insulating layers 81 and 82 as second and first insulating layers are high-k layers such as an AlO layer or a SiN layer. The layer thickness of each of the gate electrodes 30 and the insulating layers 81 and 82 is, for example, about several tens nanometers.

In addition, the semiconductor device 2 includes an insulating layer 240 that penetrates the insulating layers 82 and 81 and extends in the extending direction of the plurality of gate electrodes 30 at positions overlapping, in the Z direction, regions between the plurality of gate electrodes 30 provided at predetermined intervals in the Y direction. The insulating layer 240 as the third insulating layer is, for example, a SiO layer or a low-k layer such as a SiOC layer or an air gap layer.

In addition, the semiconductor device 2 includes a plurality of pillars 260 penetrating the insulating layer 82, the corresponding gate electrodes 30, and the insulating layer 81 instead of the pillars 60 of the first embodiment described above. Each of the plurality of pillars 260 includes a channel layer 260 constituted by a single semiconductor layer which is a composite oxide semiconductor layer such as an IGZO layer instead of a channel layer 61 including semiconductor layers 61c and 61e of the first embodiment.

Meanwhile, in a vertical transistor, a channel layer sandwiched between gate electrodes has an extension region extending to upper and lower insulating layers. In the extension region, since control by the gate electrode is weakened or hardly works, how to suppress a parasitic resistance of the extension region is the problem to be solved.

As described above, in the semiconductor device 2 of the second embodiment, the insulating layers 82 and 81, which are interlayer insulating layers on and under the gate electrodes 30, are high-k layers. As a result, the parasitic resistance of the extension regions is reduced.

At this point, as expressed by the following Inequation (1), in a case where the ratio between the capacitances of the insulating layers 81 and 82 as the high-k layers and the capacitance of the insulating layer 240 as the low-k layer or the like is within a range between 3 and 8, it is possible to make the electric field by the gate electrodes 30 act on the extension regions, whereby the parasitic capacitance in the extension regions is reduced, and the on-current of the vertical transistor is maintained. Note that the electric field acting on an extension region is also referred to as a fringe electric field.

$$\begin{matrix}[ Inequation 1 ] & \\ 3 \times ( \frac{{ε}_{high}}{{ε}_{low}} ) \times \frac{{d}_{WL} ( {R}_{WL}^{2} - {R}_{Ch}^{2} )}{{H}_{WL} {L}_{WL}} < {d}_{ext} < 8 \times ( \frac{{ε}_{high}}{{ε}_{low}} ) \times \frac{{d}_{WL} ( {R}_{WL}^{2} - {R}_{Ch}^{2} )}{{H}_{WL} {L}_{WL}} & ( 1 )\end{matrix}$$

In the above inequation, ε_{high} denotes an interlayer capacitance, namely, a capacitance of the high-k layer which is the interlayer insulating layer. ε_{low} denotes an inter-wire capacitance, namely, a capacitance of the low-k layer or the like which is an inter-wire insulating layer. Furthermore, d_{WL} denotes a distance between gate electrodes arranged in the Y direction, H_{WL} denotes a height of each gate electrode, and L_{WL} denotes a unit length of the gate electrodes. In addition, R_{WL} denotes a width at the lower end of a gate electrode, and R_{Ch} denotes a diameter of a channel layer on the lower surface of a gate electrode.

Furthermore, in the above description, as expressed by the following Inequations (2) and (3), it is based on the premise that the capacitance of the interlayer insulating layers is larger than the capacitance of the inter-wire insulating layer and the capacitance of a normal SiO layer.

$$\begin{matrix}[ Inequations 2 ] & \\ {ε}_{high} > {ε}_{low} & ( 2 )\end{matrix}$$

$${ε}_{high} > {ε}_{SiO 2} \qquad ( 3 )$$

In the above inequations, ε_{SiO2} denotes the capacitance of the SiO layer and is indicated as a reference for comparison with the interlayer capacitance ε_{high}. The capacitance ε_{SiO2} of the SiO layer is, for example, 3.9.

The inter-wire insulating layer is not necessarily a low-k layer as long as the high-k layers as the interlayer insulating layers have a sufficiently high dielectric constant and satisfies the above Inequations (1) to (3). Therefore, with the insulating layers 81 and 82 being high-k layers, the insulating layer 240 can be a SiO layer, a low-k layer, or the like as appropriate.

### (Manufacturing Method of Semiconductor Device)

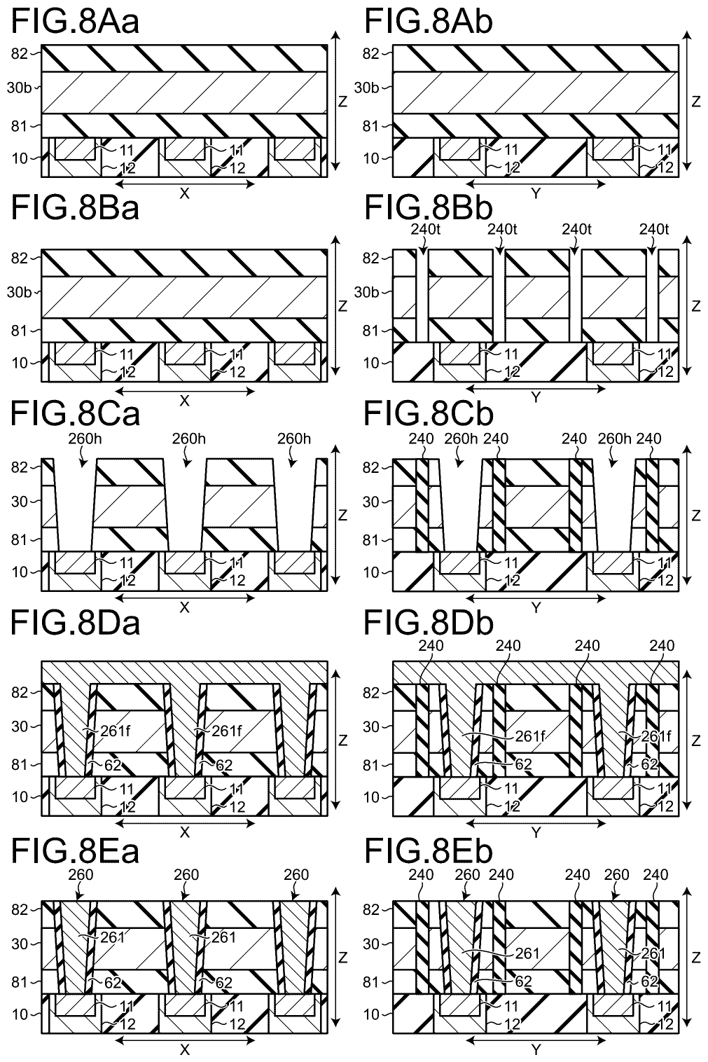

Next, an example of a manufacturing method of the semiconductor device 2 according to the second embodiment will be described with reference to FIGS. 8Aa to 8Eb. FIGS. 8Aa to 8Eb are cross-sectional views illustrating an exemplary part of a procedure of the manufacturing method of the semiconductor device 2 according to the second embodiment. More specifically, FIGS. 8Aa to 8Ea are cross-sectional views of the semiconductor device 2 in the middle of manufacturing taken in the X direction, and FIGS. 8Ab to 8Eb are cross-sectional views of the semiconductor device 2 in the middle of manufacturing taken in the Y direction.

As illustrated in FIGS. 8Aa and 8Ab, the insulating layer 10 such as a silicon nitride layer is formed on the substrate, and a plurality of contacts 12 and the plurality of lower electrodes 11 are formed in the insulating layer 10.

In addition, the insulating layer 81 such as a high-k layer, a tungsten layer 30b, and the insulating layer 82 such as a high-k layer are formed on the insulating layer 10 in the order mentioned. The tungsten layer 30b is a blanket layer that is to be processed into a pattern of the gate electrodes 30 later to become the plurality of gate electrodes 30.

As illustrated in FIGS. 8Ba and 8Bb, a plurality of through grooves 240t penetrating the insulating layer 82, the tungsten layer 30b, and the insulating layer 81 and extending along the Y direction is formed at positions deviated from the plurality of lower electrodes 11. The lower ends of the plurality of through grooves 240t are in contact with the upper surface of the insulating layer 10 between the lower electrodes 11. As a result, the tungsten layer 30b is processed into a pattern of the plurality of gate electrodes 30.

As illustrated in FIGS. 8Ca and 8Cb, the plurality of through grooves 240t is each filled with an insulating layer 240 such as a low-k layer. The insulating layers 240 are also formed on the upper surface of the insulating layer 82 but is removed by entirely etching back or the like.

In addition, a plurality of through-holes 260h penetrating the insulating layer 82, the gate electrodes 30, and the insulating layer 81 and reaching the lower electrodes 11 is formed at positions overlapping with the plurality of lower electrodes 11 in the Z direction.

As illustrated in FIGS. 8Da and 8Db, for example, the gate insulating layers 62 that cover the sidewalls of the plurality of through-holes 260h are formed by a similar method to that in the first embodiment described above. In addition, the plurality of through-holes 260h is each filled with a semiconductor layer 261f such as an IGZO layer.

As illustrated in FIGS. 8Ea and 8Eb, the semiconductor layer 261f on the upper surfaces of the insulating layers 240 is removed by CMP or the like. As a result, the semiconductor layer 261f is individually separated to become channel layers 261 constituted by a single semiconductor layer. Moreover, as a result, the plurality of pillars 260 each including a channel layer 261 and a gate insulating layer 62 is formed.

Then, the insulating layer 50 is formed, the upper electrodes 51 connected to the channel layers 261 are formed in the insulating layer 50, and plugs 52 penetrating the insulating layer 50 and connected to the upper electrodes 51 are formed, for example, by a similar method to that in the first embodiment described above.

In the above manner, the semiconductor device 2 according to the second embodiment is manufactured.

### Overview

As described above, the parasitic resistance increases in the extension regions of a channel layer extending in the vertical direction of a gate electrode. Therefore, the maximum current that can flow in the extension regions having a large parasitic resistance serves as the upper limit of the on-current of the vertical transistor. In the vertical transistors, the problem to be solved is to reduce the parasitic resistance in the extension regions and to suppress a decrease in the on-current.

In order to reduce the parasitic resistance in the extension regions, it is also conceivable to design the extension regions as short as possible. However, it is desirable that the interlayer insulating layers in which the extension regions extend has a certain layer thickness in anticipation of dishing caused by CMP or the like after the IGZO layer is formed. Therefore, there is a limit to making the extension regions short by thinning the interlayer insulating layers.

In addition, unlike a transistor using a silicon-based semiconductor material, in a vertical transistor using a composite oxide semiconductor layer such as an IGZO layer, a method of lowering a resistance value by, for example, implanting an impurity into extension regions cannot be used.

The semiconductor device 2 according to the second embodiment includes the insulating layer 81 such as a high-k layer interposed between the lower electrodes 11 and the plurality of gate electrodes 30, the insulating layer 82 such as a high-k layer interposed between the upper electrodes 51 and the plurality of gate electrodes 30, and the insulating layers 240 such as a SiO layer or a low-k layer provided between the plurality of gate electrodes 30 arranged in the Y direction and reaching the position at the height of the upper surfaces of the lower electrodes 11 from the position at the height of the lower surfaces of the upper electrodes 51.

In a gate electrode 30, a fringe electric field spreading around the gate electrode 30 is generated. As described above, by using the high-k layer for the insulating layers 81 and 82 that are interlayer insulating layers, such a fringe electric field of the gate electrodes 30 can be made to act also on the extension regions of the channel layers 260. As a result, the parasitic resistance of the extension regions can be reduced, and a decrease in the on-current of the vertical transistor can be suppressed.

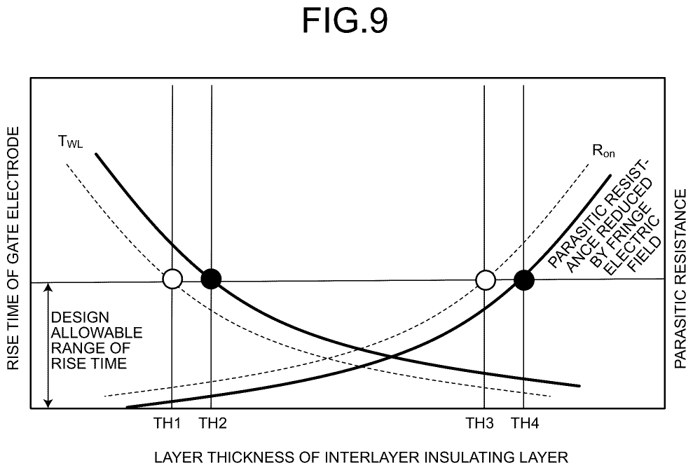

FIG. 9 is a schematic graph illustrating a relationship between the electrical characteristics and the layer thickness of an interlayer insulating layer of the semiconductor devices according to the second embodiment and a comparative example. The horizontal axis of the graph of FIG. 9 represents the layer thickness of the interlayer insulating layers. The vertical axis on the left side of the graph of FIG. 9 represents the time T_{WL} required for a rise of the current value of the gate electrode when a voltage is applied. The vertical axis on the right side of the graph of FIG. 9 represents the overall parasitic resistance Ron of the channel layer.

In FIG. 9, the electrical characteristics of the semiconductor device of the comparative example are indicated by broken lines, and the electrical characteristics of the semiconductor device 2 of the second embodiment are indicated by solid lines. The semiconductor device according to the comparative example illustrated in FIG. 9 includes SiO layers on and under a gate electrode as interlayer insulating layers.

As illustrated in FIG. 9, in the semiconductor device of the comparative example, the rise time T_{WL} of the gate electrode decreases while drawing a gentle curve as the layer thickness of the interlayer insulating layers increases. Meanwhile, the parasitic resistance Ron of the channel layer increases while drawing a gentle curve as the layer thickness of the interlayer insulating layers increases.

Incidentally, a design allowable range is defined for the rise time T_{WL} of the gate electrodes. In the semiconductor device of the comparative example, in a case where the interlayer insulating layers has a layer thickness less than or equal to TH1, an upper limit value Tmax of the rise time T_{WL} of the gate electrodes illustrated in FIG. 9 is exceeded. In addition, in a case where the interlayer insulating layer has a layer thickness greater than or equal to TH3, the on-current of the vertical transistor decreases beyond an allowable value due to an increase in the parasitic resistance Ron.

Therefore, in the semiconductor device of the comparative example, the preferable thickness of the interlayer insulating layer is in a range between the layer thickness TH1 and the layer thickness TH3.

On the other hand, in the semiconductor device 2 of the second embodiment, in a case where the interlayer insulating layers have a layer thickness less than or equal to TH2, and the upper limit value Tmax of the rise time T_{WL} of the gate electrodes is exceeded. In addition, in a case where the interlayer insulating layers have a layer thickness greater than or equal to TH4, the on-current of the vertical transistor exceeds the allowable value.

As described above, in the semiconductor device 2 according to the second embodiment, with the insulating layers 81 and 82 as the interlayer insulating layers being the high-k layers, the parasitic resistance can be reduced by the fringe electric field, and the preferred thickness of the interlayer insulating layers can be shifted to the thick film side.

Therefore, the parasitic resistance can be reduced while maintaining the layer thickness of the interlayer insulating layers in order to secure a dishing margin, whereby the characteristics of the vertical transistor can be improved. That is, by optimizing the materials of the insulating layers 81 and 82 which are interlayer insulating layers, the resistance of the vertical transistor can be reduced.

### Modification

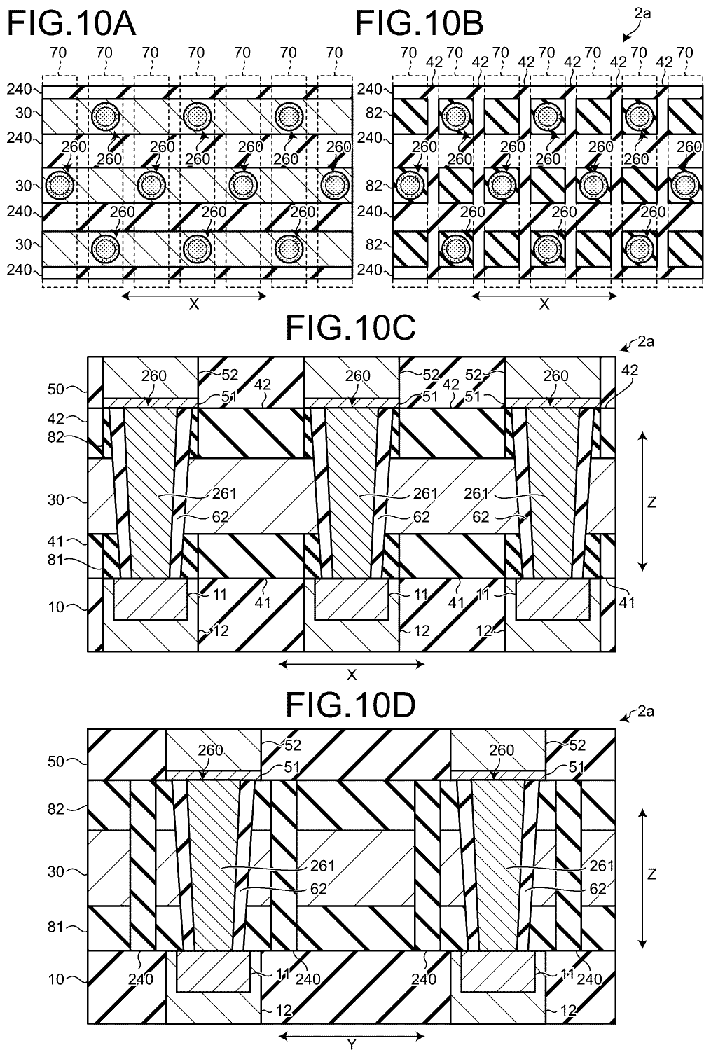

Next, a semiconductor device 2a according to a modification of the second embodiment will be described with reference to FIGS. 10A to 12C. The semiconductor device 2a of the modification is different from the above-described second embodiment in that a low-k layer or the like is used also between extension regions of channel layers 260 arranged in the X direction.

In the second embodiment, high-k layers are used as the interlayer insulating layers on and under the gate electrodes 30. However, it is preferable to use an insulating layer having a dielectric constant lower than that of a high-k layer such as a low-k layer as much as possible between layers other than the very vicinity of the extension regions of the channel layers 260. This can reduce the inter-wire capacitance, whereby the operation speed of the vertical transistor is improved.

FIGS. 10A to 10D are schematic diagrams illustrating an example of a structure of the semiconductor device 2a according to the modification of the second embodiment. FIG. 10A is an XY cross-sectional view of the semiconductor device 2a at a position at the height of gate electrodes 30. FIG. 10B is an XY cross-sectional view of the semiconductor device 2a at the position at the height of an insulating layer 82. FIG. 10C is a cross-sectional view of the semiconductor device 2a taken in the X direction. FIG. 10D is a cross-sectional view of the semiconductor device 2a taken in the Y direction.

Note that, in the following drawings, similar reference numerals are given to similar components to those of the second embodiment, and description thereof may be omitted.

As illustrated in FIGS. 10A to 10D, in the semiconductor device 2a, an insulating layer 41 is included as a third insulating layer such as a SiO layer or a low-k layer that penetrates an insulating layer 81 such as a high-k layer provided under a gate electrode 30 and extends along the Y direction between extension regions under a channel layer 260.

In the semiconductor device 2a, similarly, an insulating layer 42 is included as a third insulating layer such as a SiO layer or a low-k layer that penetrates an insulating layer 82 such as a high-k layer provided on a gate electrode 30 and extends along the Y direction between extension regions under a channel layer 260.

As a result, the semiconductor device 2a includes insulating layers 240, 41, and 42 such as a SiO layer or a low-k layer as interlayer insulating layers except for the insulating layers 81 and 82 in contact with the extension regions on and under the channel layers 260.

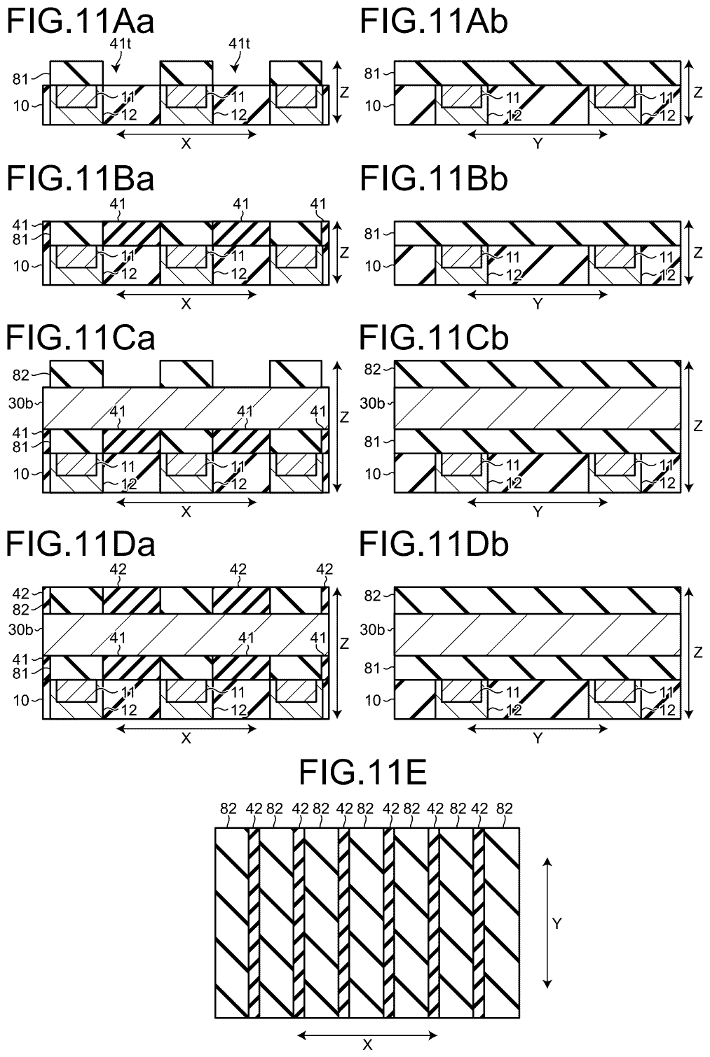

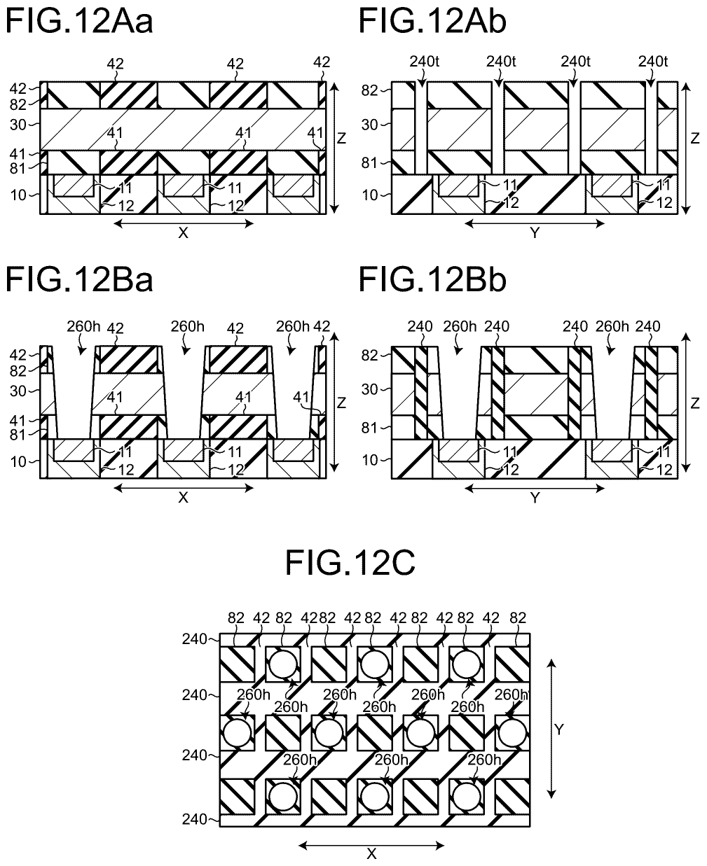

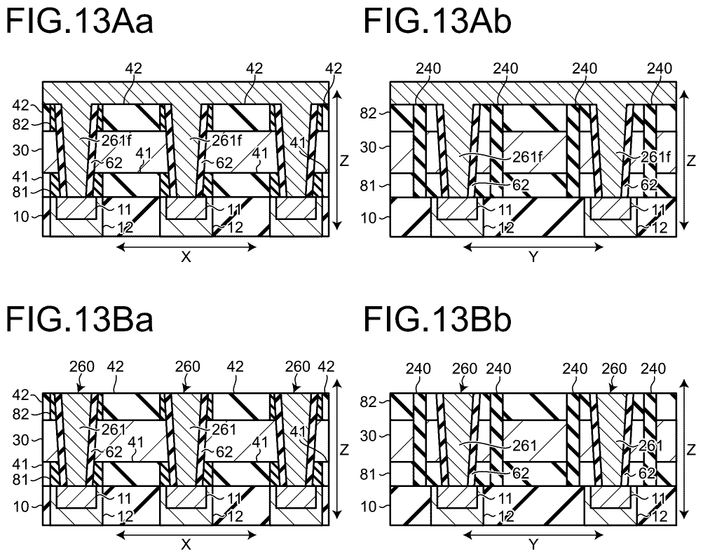

FIGS. 11Aa to 13Bb are cross-sectional views sequentially illustrating an exemplary part of a procedure of a manufacturing method of the semiconductor device 2a according to the modification of the second embodiment. More specifically, FIGS. 11Aa to 11Da, FIGS. 12Aa to 12Ba, and FIGS. 13Aa to 13Ba are cross-sectional views taken in the X direction of the semiconductor device 2a in the middle of manufacturing. FIGS. 11Ab to 11Db, 12Ab to 12Bb, and 13Ab to 13Bb are cross-sectional views of the semiconductor device 2a in the middle of manufacturing taken in the Y direction. FIGS. 11E and 12C are top views of the semiconductor device 2a in the middle of manufacturing.

As illustrated in FIGS. 11Aa and 11Ab, the insulating layer 10 such as a silicon nitride layer is formed on the substrate, and a plurality of contacts 12 and the plurality of lower electrodes 11 are formed in the insulating layer 10. Furthermore, the insulating layer 81 such as a high-k layer is formed on the insulating layer 10.

Furthermore, a plurality of through grooves 41t penetrating the insulating layer 81 and extending along the Y direction is formed while leaving portions of the insulating layer 81 overlapping the lower electrodes 11 in the Z direction.

As illustrated in FIGS. 11Ba and 11Bb, the through grooves 41t are filled with an insulating layer 41 such as a SiO layer or a low-k layer.

As illustrated in FIGS. 11Ca and 11Cb, a tungsten layer 30b and the insulating layer 82 such as a high-k layer are formed in the order mentioned on the insulating layers 81 and 41. Furthermore, a plurality of through grooves 42t penetrating the insulating layer 82 and extending along the Y direction is formed while leaving portions of the insulating layer 82 overlapping the lower electrodes 11 in the Z direction.

As illustrated in FIGS. 11Da, 11Db, and 11E, the through grooves 42t are filled with an insulating layer 42 such as a SiO layer or a low-k layer. As a result, the insulating layers 41 and 42 vertically sandwiching the tungsten layer 30b except for the positions overlapping the lower electrodes 11 in the Z direction are formed in the insulating layers 81 and 82, respectively.

As illustrated in FIGS. 12Aa and 12Ab, a plurality of through grooves 240t penetrating the insulating layer 82, the tungsten layer 30b, and the insulating layer 81 and extending along the Y direction is formed at positions deviated from the plurality of lower electrodes 11. At this point, intersecting portions with the through groove 240t of the insulating layers 41 and 42 extending in the Y direction in the insulating layers 81 and 82 may also be removed. As a result, the tungsten layer 30b is processed into a pattern of the plurality of gate electrodes 30.

As illustrated in FIGS. 12Ba, 12Bb, and 12C, the through grooves 240t is filled with an insulating layer 240 such as a SiO layer or a low-k layer. In addition, a plurality of through-holes 260h penetrating the insulating layer 82, the gate electrodes 30, and the insulating layer 81 and reaching the lower electrodes 11 is formed at positions overlapping with the plurality of lower electrodes 11 in the Z direction.

As a result, the insulating layers 81 and 82 surround the peripheries of the plurality of through-holes 260h, and the insulating layers 240, 41, and 42 extending in a lattice pattern in the X direction and the Y direction in the insulating layers 81 and 82 on and under the gate electrodes 30 are formed.

As illustrated in FIGS. 13Aa and 13Ab, for example, gate insulating layers 62 that cover the sidewalls of the plurality of through-holes 260h are formed by a similar method to that in the second embodiment described above. In addition, the plurality of through-holes 260h is each filled with a semiconductor layer 261f such as an IGZO layer.

As illustrated in FIGS. 13Ba and 13Bb, the semiconductor layer 261f on the upper surfaces of the insulating layers 240 is removed by CMP or the like. As a result, the semiconductor layer 261f is individually separated to become channel layers 261 constituted by a single semiconductor layer. Moreover, as a result, the plurality of pillars 260 each including a channel layer 261 and a gate insulating layer 62 is formed.

Then, an insulating layer 50 is formed, upper electrodes 51 connected to the channel layers 260 are formed in the insulating layer 50, and plugs 52 penetrating the insulating layer 50 and connected to the upper electrodes 51 are formed, for example, by a similar method to that in the first embodiment described above.

In the above manner, the semiconductor device 2a according to the modification is manufactured.

According to the semiconductor device 2a of the modification, at the position at the height of the insulating layers 81 and 82, the insulating layers 41 and 42 such as a SiO layer or a low-k layer are also included between the plurality of channel layers 260 arranged in the Y direction. As a result, the dielectric constant of the interlayer insulating layers can be lowered, and the speed of operation of the vertical transistor can be further increased.

According to the semiconductor device 2a of the modification, other effects similar to those of the semiconductor device 2 of the second embodiment described above are achieved.

### Other Modifications

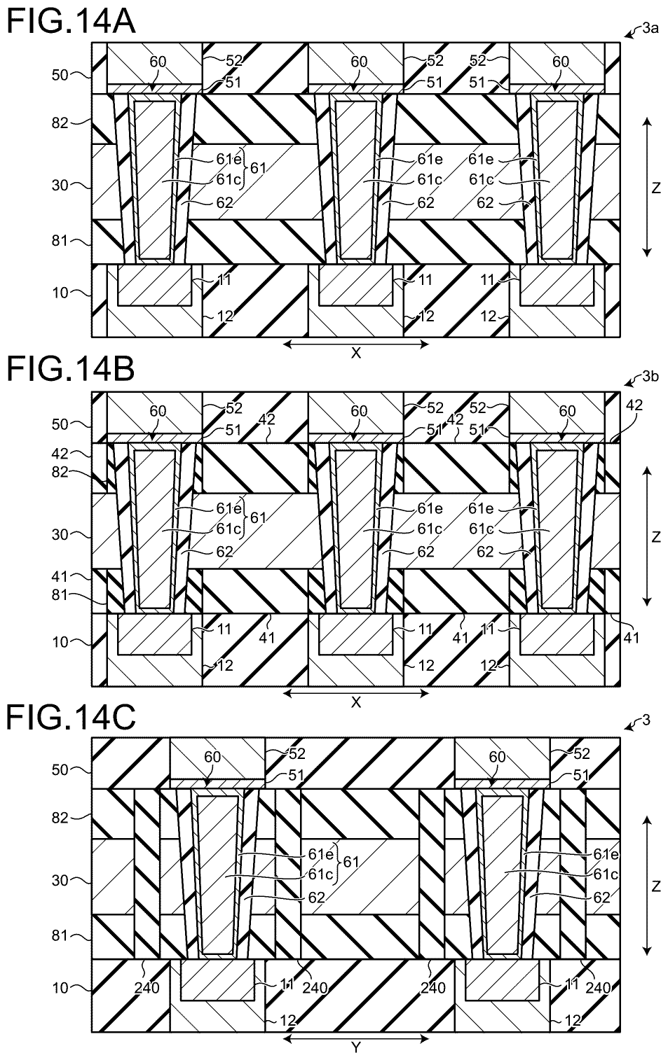

In the second embodiment and the modification described above, the channel layers 261 of the vertical transistors include a single semiconductor layer. However, it is also possible to apply a channel layer 61 including semiconductor layers 61c and 61e of the first embodiment and the modification to these structures including the insulating layers 240, 41, 42, 81, and 82 as the interlayer insulating layers. An example is illustrated in FIGS. 14A to 14C.

FIGS. 14A to 14C are schematic diagrams illustrating exemplary structures of semiconductor devices 3 according to other modifications. More specifically, FIG. 14A is a cross-sectional view of a semiconductor device 3a, to which the structure of the second embodiment described above is applied, taken in the X direction. FIG. 14B is a cross-sectional view of a semiconductor device 3b, to which the structure of the modification of the second embodiment described above is applied, taken in the X direction. FIG. 14C is a cross-sectional view of the semiconductor devices 3 (3a and 3b) taken in the Y direction.

As illustrated in FIGS. 14A to 14C, the semiconductor devices 3 include a channel layer 61 including a semiconductor layer 61c such as an IGZO layer serving as a core portion of a channel layer 61 and a semiconductor layer 61e such as an IGZO layer covering the semiconductor layer 61c and having a higher content rate of a metal having a higher carrier concentration such as In than that of the semiconductor layer 61c, similarly to the above-described first embodiment.

As illustrated in FIGS. 14A and 14C, the semiconductor device 3a including such channel layers 61 may include insulating layers 81 and 82 such as a high-k layer as interlayer insulating layers and an insulating layer 240 such as a SiO layer or a low-k layer as an inter-wire insulating layer, similarly to the above-described the second embodiment.

As illustrated in FIG. 14B, such a semiconductor device 3b may further include insulating layers 41 and 42 such as a SiO layer or a low-k layer as interlayer insulating layers excluding the vicinity of extension regions of the channel layers 61.

Furthermore, apart from the examples of FIGS. 14A to 14C, a semiconductor layer having a high In concentration and covering the peripheries of the semiconductor layers 61c may have a layer thickness of greater than or equal to 5 nm and less than or equal to the layer thickness of an interlayer insulating layer at at least one of the upper ends or the lower ends of the semiconductor layers 61c similarly to the modification of the first embodiment described above.

According to the semiconductor devices 3 of the other modifications, similar effects as those of the first and second embodiments and the modifications described above are achieved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first electrode;
a first insulating layer provided on the first electrode;
a gate electrode provided on the first insulating layer;
a second insulating layer provided on the gate electrode;
a second electrode provided on the second insulating layer;
a channel layer having one end connected to the first electrode and another end connected to the second electrode; and
a gate insulating layer provided between the channel layer and the gate electrode, between the channel layer and the first insulating layer, and between the channel layer and the second insulating layer,
wherein the channel layer includes:
a first semiconductor layer based on a composite oxide semiconductor containing a plurality of metals;
a second semiconductor layer provided between the first semiconductor layer and the first electrode; and
a third semiconductor layer provided between the first semiconductor layer and the second electrode, and
the second and third semiconductor layers are based on another composite oxide semiconductor containing metals of same types as the metals of the first semiconductor layer, the another composite oxide semiconductor having a metal among the plurality of metals having a higher carrier concentration than other metals, the metal having a higher content rate in the second and third semiconductor layers than in the first semiconductor layer.

2. The semiconductor device according to claim 1,
wherein the composite oxide semiconductor as a primary component of the channel layer is IGZO containing In, Ga, and Zn, and
an In concentration of the second and third semiconductor layers is higher than an In concentration of the first semiconductor layer.

3. The semiconductor device according to claim 1,
wherein the channel layer further includes a fourth semiconductor layer provided between the first semiconductor layer and the gate insulating layer, and
the fourth semiconductor layer is based on a further composite oxide semiconductor containing metals of same types as the metals of the first semiconductor layer, the metal having a higher content rate in the fourth semiconductor layer than in the first semiconductor layer.

4. The semiconductor device according to claim 3,
wherein a thickness of at least one of the second or third semiconductor layer is greater than or equal to 5 nm, and
a thickness of the fourth semiconductor layer is less than or equal to 5 nm.

5. The semiconductor device according to claim 4,
wherein the thickness of the third semiconductor layer is less than or equal to the thickness of the second insulating layer.

6. The semiconductor device according to claim 1,
wherein the first and second insulating layers contain at least one of SiO, SiOC, or an air gap.

7. The semiconductor device according to claim 6,
wherein the first and second insulating layers are low-k layers.

8. A semiconductor device comprising:
a first electrode;
a second electrode provided above the first electrode;
a plurality of gate electrodes extending in a first direction along a plane direction of the first and second electrodes, the plurality of gate electrodes being provided between the first and second electrodes at predetermined intervals in a second direction intersecting the first direction along the plane direction of the first and second electrodes;
a first insulating layer interposed between the first electrode and the plurality of gate electrodes;
a second insulating layer interposed between the second electrode and the plurality of gate electrodes;
a plurality of channel layers each provided at positions overlapping with the plurality of gate electrodes when viewed from a stacking direction of the first electrode, the plurality of gate electrodes, and the second electrode, the plurality of channel layers each having one end portion and another end portion respectively connected to the first and second electrode overlapping with a corresponding gate electrode in a vertical direction among the plurality of gate electrodes;
a gate insulating layer provided between each of the plurality of channel layers and the corresponding gate electrode, between each of the plurality of channel layers and the corresponding first insulating layer, and between each of the plurality of channel layers and the corresponding second insulating layer; and
a third insulating layer provided between the plurality of gate electrodes arranged in the second direction, the third insulating layer reaching a position at a height of an upper surface of the first electrode from a position at a height of a lower surface of the second electrode,
wherein a dielectric constant of the third insulating layer is lower than dielectric constants of the first and second insulating layers.

9. The semiconductor device according to claim 8,
wherein the first and second insulating layers contain at least one of AlO or SiN, and
the third insulating layer contains at least one of SiO, SiOC, or an air gap.

10. The semiconductor device according to claim 9,
wherein the first and second insulating layers are high-k layers, and
the third insulating layer is a low-k layer.

11. The semiconductor device according to claim 8,
wherein the plurality of channel layers is arranged in the second direction in such a manner as to respectively overlap with the plurality of gate electrodes and included in extending directions of the plurality of gate electrodes at predetermined intervals in the first direction, and
the third insulating layer is also included between the plurality of channel layers arranged in the first direction at a position at a height of the second insulating layer.

12. The semiconductor device according to claim 11,
wherein the third insulating layer is also included between the plurality of channel layers arranged in the first direction at a position at a height of the first insulating layer.

13. The semiconductor device according to claim 8,
wherein each of the plurality of channel layers includes:
a first semiconductor layer based on a composite oxide semiconductor containing a plurality of metals;
a second semiconductor layer provided between the first semiconductor layer and the first electrode; and
a third semiconductor layer provided between the first semiconductor layer and the second electrode, and
the second and third semiconductor layers are based on another composite oxide semiconductor containing metals of same types as the metals of the first semiconductor layer, the another composite oxide semiconductor having a metal among the plurality of metals having a higher carrier concentration than other metals, the metal having a higher content rate in the second and third semiconductor layers than in the first semiconductor layer.

14. The semiconductor device according to claim 13,
wherein the composite oxide semiconductor as a primary component of the plurality of channel layers is IGZO containing In, Ga, and Zn, and
an In concentration of the second and third semiconductor layers is higher than an In concentration of the first semiconductor layer.

15. The semiconductor device according to claim 13,
wherein the plurality of channel layers further includes a fourth semiconductor layer provided between the first semiconductor layer and the gate insulating layer, and
the fourth semiconductor layer is based on a further composite oxide semiconductor containing metals of same types as the metals of the first semiconductor layer, the metal having a higher content rate in the fourth semiconductor layer than in the first semiconductor layer.

16. The semiconductor device according to claim 15,
wherein a thickness of at least one of the second semiconductor layer or the third semiconductor layer is greater than or equal to 5 nm, and
a thickness of the fourth semiconductor layer is less than or equal to 5 nm.

17. The semiconductor device according to claim 16,
wherein the thickness of the third semiconductor layer is less than or equal to the thickness of the second insulating layer.
